(19) United States
(12) Patent Application Publication
(10) Pub. No.: US 2006/0216917 A1
(43) Pub. Date: Sep. 28, 2006

(54) Method for forming recess gate of semiconductor device

(75) Inventor: Won Sun Seo, Gyeonggi-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/321,596

(22) Filed: Dec. 30, 2005

(30) Foreign Application Priority Data
Mar. 23, 2005 (KR) 10-2005-0024161

(51) Int. Cl. H01L 21/4763

(52) U.S. Cl. 438/589; 438/591; 438/684

(57) ABSTRACT

Provided is a method for semiconductor device. In formation of a RCAT (Recess Channel Array Transistor) for increasing a channel length of a gate, that is, a recess gate, a gate polysilicon layer is formed while a pad nitride film pattern is not removed, and then a gate having a narrower line-width than that of a recess gate region is formed so as to improve a process margin, prevent generation of parasite capacitors and reduce leakage current, thereby improving electric characteristics of a semiconductor device.

### BACKGROUND OF THE INVENTION

1. Field of the Invention

The present invention generally relates to a method for manufacturing a semiconductor device, and more specifically, to a method for manufacturing a semiconductor device wherein a gate polysilicon layer is formed while a pad nitride film pattern is not removed, and a gate having a narrower line-width than a recess gate region is formed so as to improve a process margin and prevent generation of parasite capacitors and reduce leakage current in formation of a Recess Channel Array Transistor (hereinafter, referred to as “RCAT”), that is, recess gate is formed to increase the channel length of the gate, thereby improving electric characteristics.

2. Description of the Related Art

Due to high-integration of semiconductor devices, a line-width of a gate becomes narrower and a channel length becomes shorter, which results in degradation of characteristics of semiconductor devices. Since this problem affects the process of 100 nm or less, recess gate technology is applied in order to overcome the problem. The recess gate is obtained by etching an active region of a semiconductor substrate at a predetermined thickness and increasing the contact area between the active region and the gate to increase the channel length.

FIG. 1 is a plane view illustrating a semiconductor device.

Referring to FIG. 1, a recess gate region 45 is formed on an active region 20 located at the bottom of a gate 80. The line-width of the recess gate region 45 is formed narrower than that of the gate 80.

FIGS. 2a through 2f are cross-sectional views illustrating a method for manufacturing a semiconductor device. FIGS. 2a through 2e show the cross-sections according to i-i′ of FIG. 1.

Referring to FIG. 2a, a buffer oxide film 30 and a barrier polysilicon layer 40 are sequentially deposited on a semiconductor substrate 10 having a device separating film (not shown).

The buffer oxide film 30 protects the semiconductor substrate 10 when the barrier polysilicon layer 40 is etched which is used as a hard mask for formation of a RCAT.

Referring to FIG. 2b, the barrier polysilicon layer 40 of a recess gate-to-be region is etched to form a recess gate region 45. Then, the buffer oxide film 30 and the active region 20 of the semiconductor substrate 10 are etched with the barrier polysilicon layer 40 as an etching mask.

Referring to FIG. 2c, after the barrier polysilicon layer 40 is removed, a gate oxide film 35 having a predetermined thickness is formed on the entire surface of the resultant structure.

Referring to FIG. 2d, a gate polysilicon layer 50 for filling the recess gate region 45 is formed. Then, a gate metal layer 60 and a gate hard mask layer 70 are sequentially formed thereon.

Referring to FIG. 2e, a photoresist pattern (not shown) that defines a gate is formed on the gate hard mask layer 70. Then, the gate hard mask layer 70, the gate metal layer 60 and the gate polysilicon layer 50 are sequentially etched with the photoresist pattern as a mask to form a gate 80.

FIG. 2f shows the cross-section according to ii-ii′ of FIG. 1 which is vertical to that of FIG. 2e. Since the gate polysilicon layer 50 is formed on the device separating film 25, a parasitic capacitor is generated from the gate polysilicon layer 50 filled in the recess gate region 45.

Also, as a space between two gates 80 that pass one active region 20 becomes narrower, leakage current is generated to cause Gate Induced Drain Leakage (hereinafter, referred to as “GIDL”). As a result, mis-arrangement between the recess gate region and the gate mask is generated during the formation of the gate 80, so that it is difficult to secure the process margin, thereby reducing process yield and degrading electric characteristics.

### SUMMARY OF THE INVENTION

Various embodiments are directed at providing a method for manufacturing a semiconductor device wherein a recess gate region is formed while a pad nitride film pattern is not removed, a gate polysilicon layer is formed, and then a gate having a narrower line-width than that of the recess gate region is formed, thereby preventing generation of parasitic capacitors and reducing leakage current to improve electric characteristics.

According to one embodiment of the present invention, a method for manufacturing a semiconductor device comprises the steps of:

(a) defining an active region and an isolation region on a semiconductor substrate where a pad oxide film and a pad nitride film are formed;

(b) etching the pad nitride film and the pad oxide film and a predetermined depth of the semiconductor substrate of the active region to form a recess;

(c) forming a gate oxide on the surface of the recess gate region;

(d) forming a planarized gate polysilicon layer on the entire surface of the resultant;

(e) performing a CMP process until the pad nitride film is exposed; and

(f) forming and patterning a gate metal layer and a gate hard mask layer on the entire surface of the resultant structure to form a gate.

### BRIEF DESCRIPTION OF THE DRAWINGS

Other aspects and advantages of the present invention will become apparent upon reading the following detailed description and upon reference to the drawings in which:

FIG. 1 is a plane view illustrating a semiconductor device;

FIGS. 2a through 2f are cross-sectional views illustrating a method for manufacturing a semiconductor device;

FIG. 3 is a plane view illustrating a semiconductor device according to an embodiment of the present invention;

FIGS. 4a through 4f are cross-sectional views illustrating a method for manufacturing a semiconductor device according to one embodiment of the present invention;

FIG. 5 is a cross-sectional view illustrating a method for manufacturing a semiconductor device according to one embodiment of the present invention; and

FIGS. 6a through 6c are cross-sectional views illustrating a method for manufacturing a semiconductor device according to another embodiment of the present invention.

### DETAILED DESCRIPTION OF THE EXEMPLARY EMBODIMENTS

The present invention will be described in detail with reference to the accompanying drawings. Wherever possible, the same reference numbers will be used throughout the drawings to refer to the same or like parts.

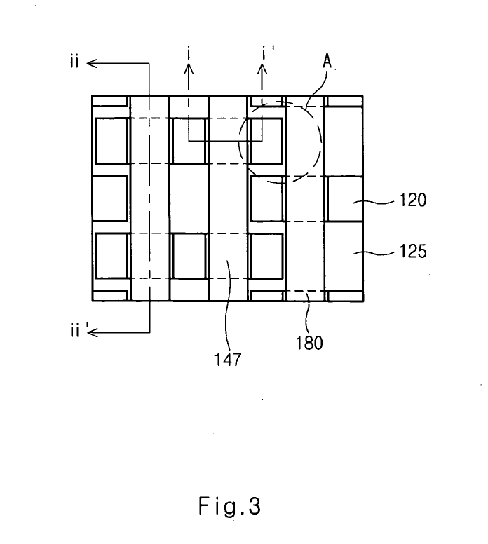

FIG. 3 is a plane view illustrating a semiconductor device according to an embodiment of the present invention.

Referring to FIG. 3, a recess gate region 147 is formed to have a broader line-width of that of a gate 180. AS a result, a gate polysilicon layer formed on the recess gate region 147 is shown at both sides of the gate 180 that passes an active region 120.

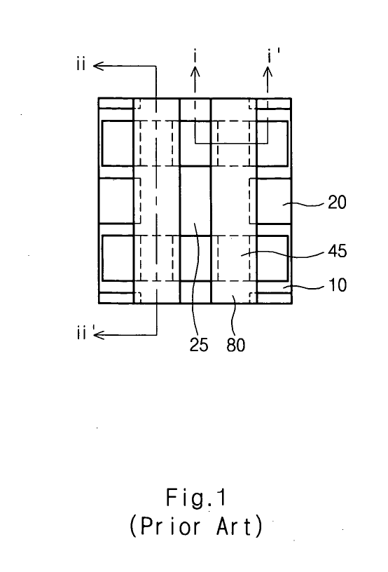

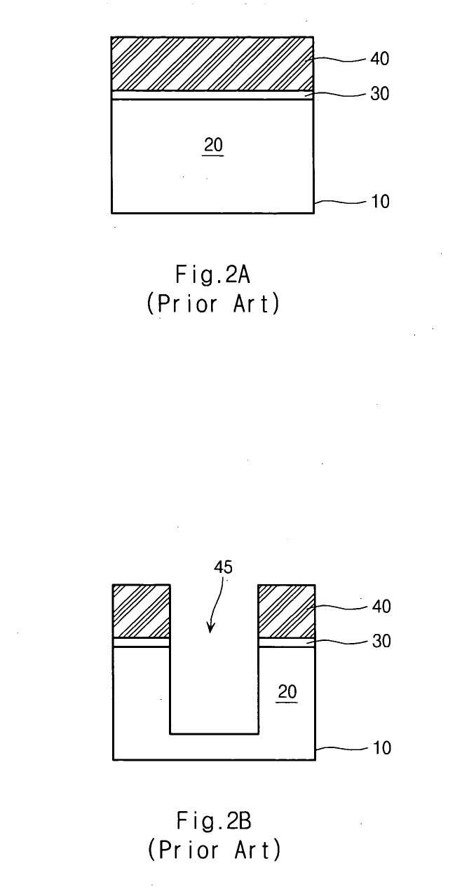

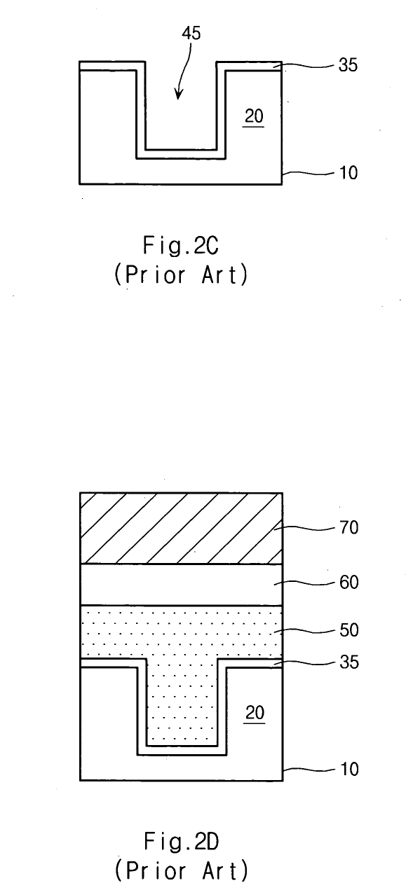

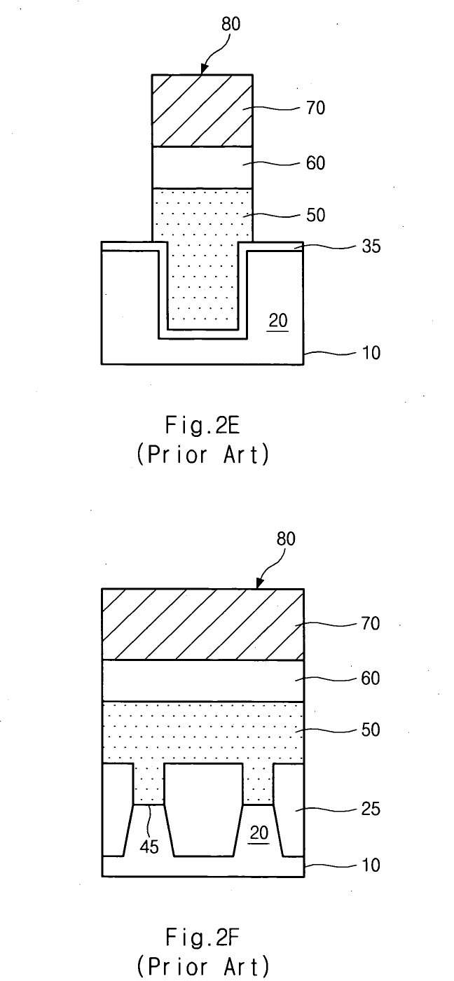

While the gate 80 is overlapped with the edge of the active region 20 in the prior art of FIG. 1, the gate 180 is not overlapped with the edge of the active region 120 as shown in ‘A’ of FIG. 3.

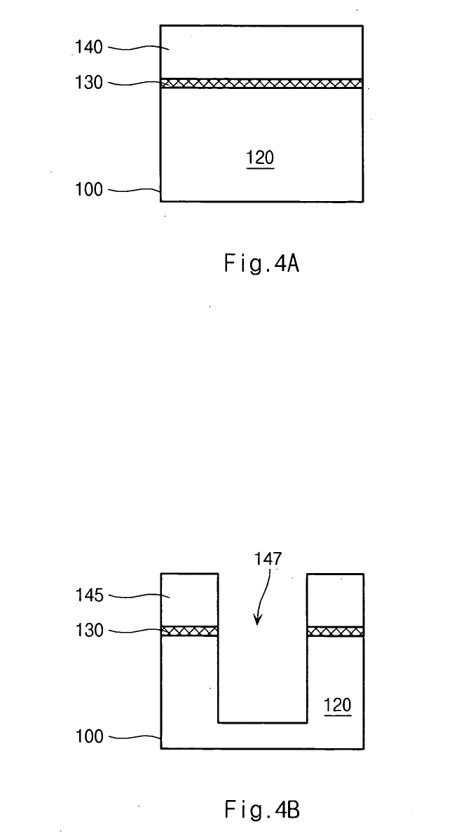

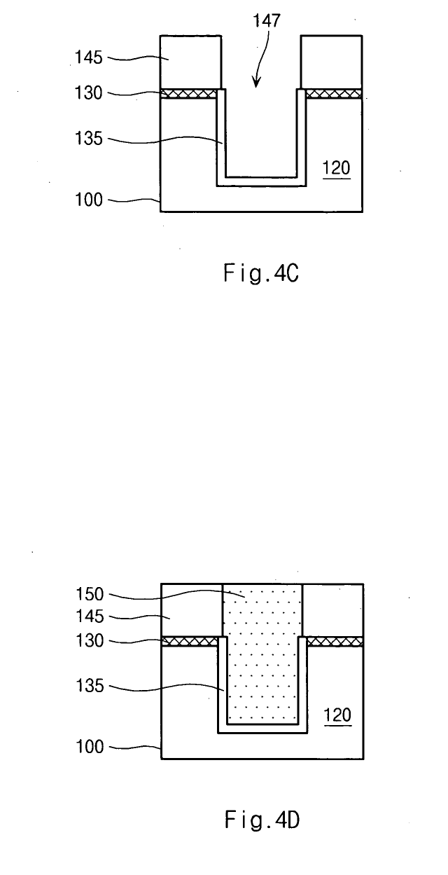

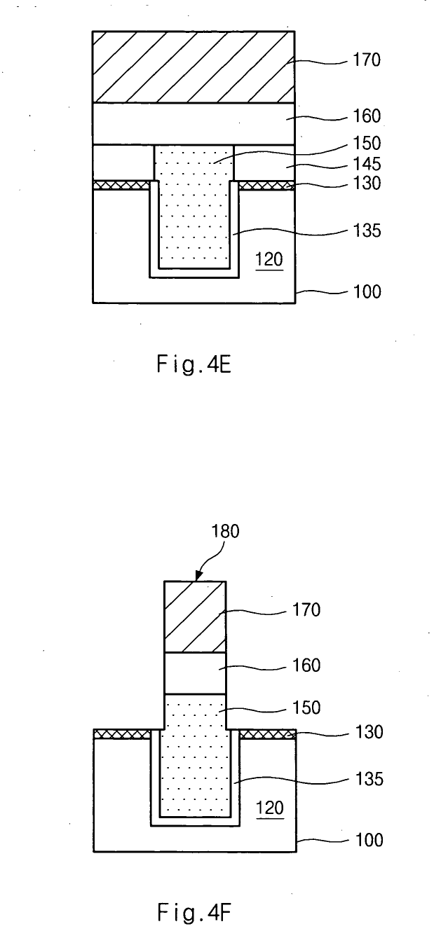

FIGS. 4a through 4f are cross-sectional views illustrating a method for manufacturing a semiconductor device according to one embodiment of the present invention.

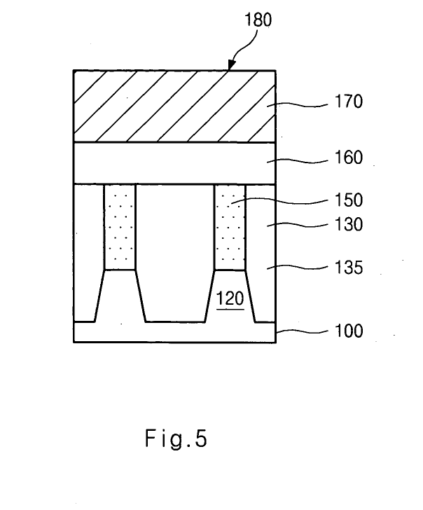

FIGS. 4a through 4f show the cross-sections according to i-i′ of FIG. 3, and FIG. 5 shows the cross-section according to ii-ii′ of FIG. 3.

Referring to FIG. 4a, a pad oxide film 130 and a pad nitride film 140 are sequentially formed on the entire surface of a semiconductor substrate 100. Then, a trench (not shown) is formed on an isolation-to-be region with an isolation mask that defines the active region 120.

Thereafter, an oxide film for filling the trench is formed on the entire surface of the resultant structure, and a CMP process is performed to planarized the entire surface of the resultant structure.

Preferably, the CMP process is performed until the pad nitride film 140 is exposed.

Referring to FIG. 4b, a photoresist pattern (not shown) that defines a recess gate region (not shown) is formed. Then, the pad nitride film 140 is selectively etched with the photoresist pattern (not shown) as a mask to form a pad nitride film pattern 145 that exposes the recess gate region (not shown). Next, the pad oxide film 130 and the semiconductor substrate 100 having a predetermined depth are etched with the pad nitride film pattern 145 as an etching mask to form a recess gate region 147. It is preferable to regulate the line-width and the thickness of the recess gate region in consideration of a storage node contact region and a bit line contact region.

Referring to FIG. 4c, a gate oxide film 135 is formed on the surface of the recess gate region 147 and side walls of pad oxide film 130.

Referring to FIG. 4d, a gate polysilicon layer 150 is formed on the entire surface of the semiconductor substrate 100 including the recess gate region 147, and a CMP process is performed until the pad nitride film pattern 145 is exposed.

The CMP process is performed using the pad nitride film pattern 145 as an ending point or when the pad oxide film 130 is exposed.

Referring to FIG. 4e, a gate metal layer 160 and a gate hard mask layer 170 are formed on the entire surface of the resultant structure.

Referring to FIG. 4f, a gate 180 overlapped with the recess gate region 147 is patterned to have its line-width narrower than the width of the recess gate region 147.

Referring to FIG. 5, the gate polysilicon layer 150 of the recess gate region 147 contacts directly with the gate metal layer 160 in the cross section perpendicular to that of FIG. 4f.

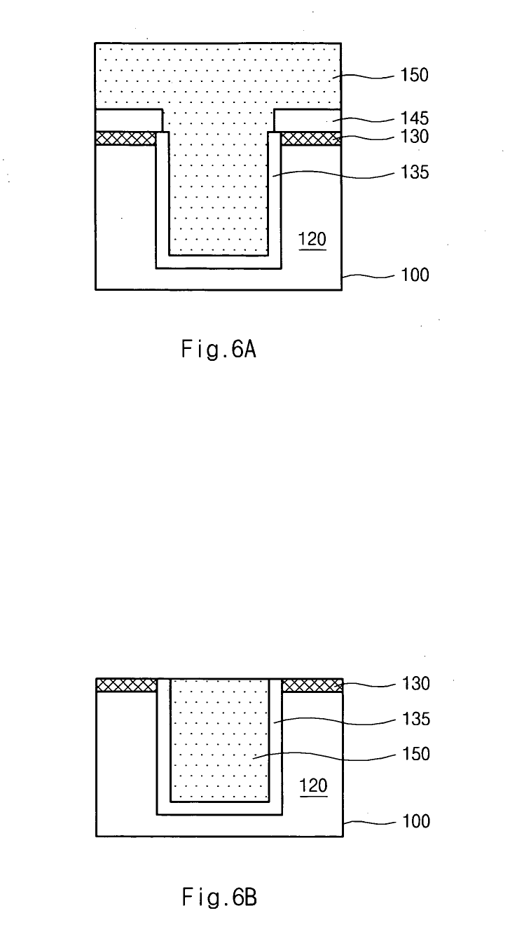

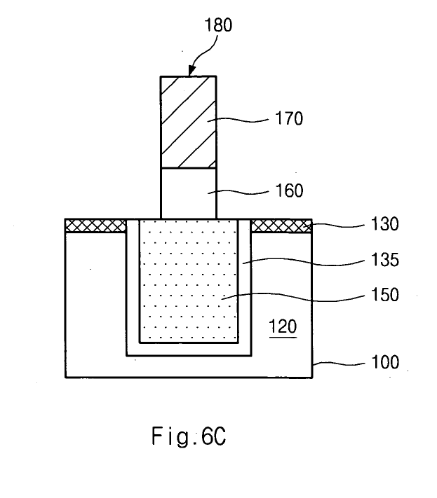

FIGS. 6a through 6c are cross-sectional views illustrating a method for manufacturing a semiconductor device according to another embodiment of the present invention.

The formation of a recess gate region on a semiconductor substrate and a polysilicon layer for filling the recess gate region is performed like the procedure shown in FIGS. 3a and 3b.

Referring to FIG. 6a, a pad oxide film 130 and a pad nitride film pattern 145 are formed on a semiconductor substrate 100, and a recess gate region 147 is formed with the pad oxide film 130 and the pad nitride film 145 as an etching mask.

A gate oxide film 135 having a predetermined thickness is formed on the surface of the semiconductor substrate 100 of the recess gate region 147. Then, a gate polysilicon layer 150 is formed on the entire surface of the semiconductor substrate 100 including the recess gate region 147.

Referring to FIG. 6b, a CMP process is performed to remove the gate polysilicon layer 150 and the pad nitride film pattern 145 on the semiconductor susbtrate 100. Here, the pad oxide film 135 is formed to have the same height as that of the polysilicon layer 150. Preferably, the CMP process is performed so that the polysilicon layer 150 may remain only on the inside of the recess gate region 147.

Referring to FIG. 6c, a gate metal layer 160 and a gate hard mask layer 170 are formed on the planarized semiconductor substrate 100, and patterned to form a gate 180.

Preferably, the gate 180 is formed to have a narrower line-width of the gate polysilicon layer 150.

In this embodiment, the gate polysilicon layer 150 is not formed higher than the surface of the semiconductor substrate, thereby reducing parasitic capactitors.

Also, a contact region corresponding to the narrowed gate line-width can be secured, and voids between gates due to the small aspect ratio of the gate can be prevented during a subsequent processes for forming a nitride film spacer and an interlayer insulating film.

As described above, according to an embodiment of the present invention, a gate polysilicon layer is formed while a pad nitride film pattern is not removed, so that a gate having a narrower line-width than the width of a recess gate region is formed, thereby preventing generation of parasite capacitors and reducing leakage current.

Also, mis-arrangement of the recess gate region and the gate can be prevented when the gate is formed, thereby improving yield and electric characteristics of a semiconductor device.

The foregoing description of various embodiments of the invention has been presented for purposes of illustrating and description. It is not intended to be exhaustive or to limit the invention to the precise form disclosed, and modifications and variations are possible in light of the above teachings or may be acquired from practice of the invention. Thus, the embodiments were chosen and described in order to explain the principles of the invention and its practical application to enable one skilled in the art to utilize the invention in various embodiments and with various modifications as are suited to the particular use contemplated.

What is claimed is:

1. A method for manufacturing a semiconductor device, comprising the steps of:
(a) defining an active region and an isolation region on a semiconductor substrate where a pad oxide film and a pad nitride film are formed;
(b) etching the pad nitride film and the pad oxide film and a predetermined depth of the semiconductor substrate in the active region to form a recess;
(c) forming a gate oxide film on a surface of the recess gate region;
(d) forming a planarzied gate polysilicon layer on an entire surface of the resultant;
(e) performing a CMP process until the pad nitride film is exposed; and
(f) forming and patterning a gate metal layer and a gate hard mask layer on the entire surface of a resultant structure to form a gate.

2. The method according to claim 1, wherein the CMP process of the step (e) is performed using the pad nitride film as an ending point.

3. The method according to claim 1, wherein the gate of the step (f) has a line-width narrower than a width of the recess.
